(19) United States
(12) Patent Application Publication
(10) Pub. No.: US 2002/0127795 A1
(43) Pub. Date: Sep. 12, 2002

(54) Semiconductor device having trench capacitor and method for manufacturing the same

(75) Inventor: Pen-Chen Shih, Yunlin Hsien (TW)

Correspondence Address: Richard P. Berg, Esq., c/o LADAS & PARRY, Suite 2100, 5670 Wilshire Boulevard, Los Angeles, CA, 90036-5679, US

(73) Assignee: Winbond Electronics Corp.

(21) Appl. No.: 09/885,210

(22) Filed: Jun. 20, 2001

(30) Foreign Application Priority Data
Mar. 6, 2001 (TW) 90105155

(51) Int. Cl. H01L 21/8242; H01L 27/108; H01L 29/76; H01L 29/94; H01L 31/119; H01L 21/336; H01L 21/20

(52) U.S. Cl. 438/243; 438/244; 257/301; 438/303

(57) ABSTRACT

A semiconductor device having a trench capacitor is provided, which includes a semiconductor substrate having a trench formed thereon, in which the semiconductor substrate serves as a first bottom plate; a first conductive structure formed in the trench, in which a bottom of the first conductive structure is electrically connected to the semiconductor substrate to serve as a second bottom plate; a first dielectric layer formed on the sidewall of the trench; a second conductive structure isolatedly formed around the first conductive structure to serve as a top plate; a second dielectric layer formed between the first conductive structure and the second conductive structure to isolate the first conductive structure and the second conductive structure; and a third conductive structure formed on the semiconductor substrate and electrically connected to the second conductive structure.

### BACKGROUND OF THE INVENTION

1. Field of the Invention

The present invention relates to a technology for manufacturing integrated semiconductor circuits, which is particularly suitable for applying to the fabrication of a trench capacitor structure in dynamic access memory (DRAM).

2. Description of the Related Art

FIG. 10 is a circuit diagram illustrating a conventional DRAM cell. As shown in FIG. 10, the memory cell includes a metal oxide semiconductor (MOS) transistor indicated by the symbol T and a storage capacitor indicated by the symbol C. The source of the transistor T is connected to the bit line BL. The drain is connected to the top plate 6 (i.e., storage electrode) of the capacitor C. The gate of the transistor is connected to the word line WL. The bottom plate 8 of the capacitor C is connected to a predetermined voltage such as ground. Additionally, a dielectric layer is formed between the plates 6 and 8.

In order to assure that the data can be correctly read out from the memory cell, a trench capacitor which can increase the capacitance is disclosed in the prior arts such as U.S. Pat. No. 5,874,335.

However, with the increase in the integration of semiconductor memory devices, the capacitance of the storage capacitor formed in a trench having a predetermined depth can not meet growing industry requirements.

### SUMMARY OF THE INVENTION

Accordingly, an object of the present invention is to provide a semiconductor device having a trench capacitor, which can increase the capacitance without increasing the trench depth by filling a concentric ring of dielectric layer with a conductive material to form parallel capacitors.

The semiconductor device having a trench capacitor according to the present invention, includes a semiconductor substrate having a trench serving as a first bottom plate; a first conductive structure formed in the trench, in which the bottom of the first conductive structure is electrically connected to the semiconductor substrate to serve as a second bottom plate; a first dielectric layer formed on the sidewall of the trench; a second conductive structure isolatedly formed on the circumference of the first conductive structure to serve as a top plate; a second dielectric layer, formed between the first conductive structure and the second conductive structure, for isolating the first conductive structure and the second conductive structure; and a third conductive structure formed on the semiconductor substrate and connected to the second conductive structure.

The semiconductor substrate, the first dielectric layer and the second conductive structure constitute a first capacitor. The first conductive structure, the second dielectric layer and the third conductive structure constitute a second capacitor. The first capacitor and the second capacitor are connected in parallel to increase the capacitance.

Moreover, the trench and the first conductive structure are cylindrical, and the second conductive structure is ring-shaped. The height of the first conductive structure is less than that of the second conductive structure.

The semiconductor device further comprises a sidewall isolator, formed on the top of the trench, for isolating the third conductor structure and the semiconductor substrate.

The semiconductor substrate is single crystalline silicon having a first conductive dopant such as n-type or p-type dopant. The first conductive structure, the second conductive structure and the third conductive structure are all polysilicon or Amorphous si having a dopant whose conductivity is the same as that of the semiconductor substrate.

Furthermore, the first dielectric layer and the second dielectric layer can be a composite material of SiO₂/Si₃N₄/SiO₂ or Si3N₄/SiO₂.

In order to achieve the above object, this invention provides a method for manufacturing a semiconductor device, which comprises the steps of: first providing a semiconductor substrate having a trench, in which the semiconductor substrate serves as a first bottom plate; forming a first conductive structure in the trench to serve as a second bottom plate; forming a first dielectric layer and a second dielectric layer on the sidewall of the trench and the first conductive structure, respectively; forming a second conductive structure between the first dielectric layer and the second dielectric layer to serve as a top plate; forming a third conductive structure for electrically connecting to the second conductive structure.

In the above method, the process for forming the first conductive structure further comprises the steps of: depositing an oxide layer on the area except the center of the trench; anisotropically etching the oxide layer to expose the semiconductor substrate; filling the center of the trench with a first conductive layer; removing the first conductive layer outside the trench to form a first conductive structure lower than the trench.

Furthermore, in the above method, a step of removing the oxide layer can be performed before the step of forming the first dielectric layer and the second dielectric layer.

Prior to the step of forming the third conductive structure, the above method can further comprise a step of forming a sidewall isolator on the top of the trench to isolate the third conductive structure and the semiconductor substrate.

### BRIEF DESCRIPTION OF THE DRAWINGS

The present invention can be more fully understood by reading the subsequent detailed description in conjunction with the examples and references made to the accompanying drawings, wherein:

FIG. 1 to FIG. 8 are cross-sectional views illustrating the manufacturing process of a semiconductor device having a trench capacitor according to an embodiment of this invention;

FIG. 9 is a circuit diagram of a DRAM cell having a trench capacitor of this invention; and

FIG. 10 is a circuit diagram of a conventional DRAM cell.

### DETAILED DESCRIPTION OF THE PREFERRED EMBODIMENT

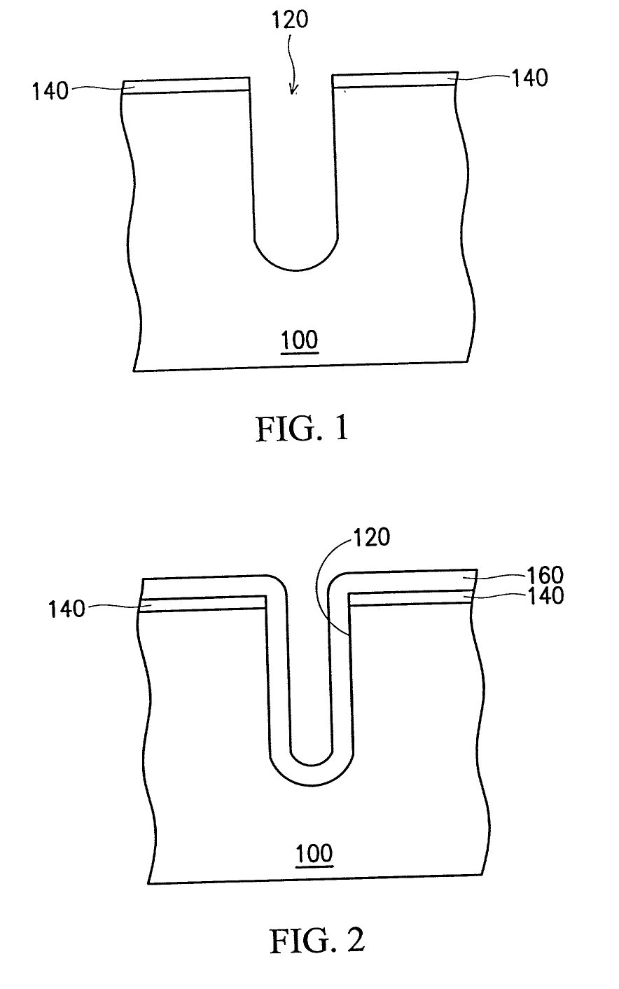

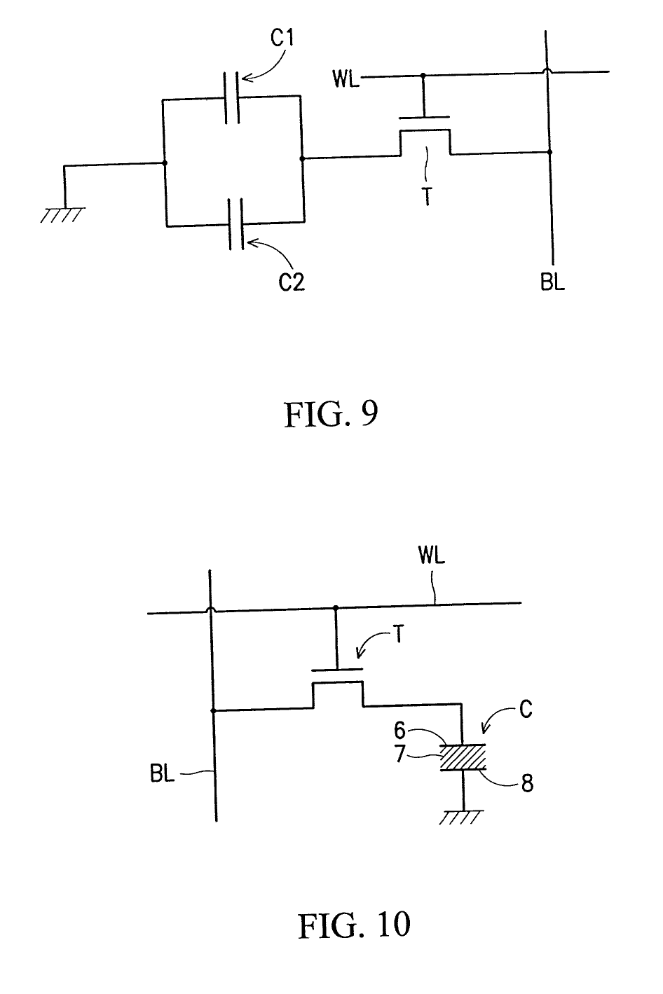

The preferred embodiment of this invention is described below together with FIGS. 1˜8 and FIG. 9.

Referring to FIG. 1, a semiconductor substrate 100 is provided to serve as a bottom plate, in which the semiconductor substrate 100 is single crystalline silicon having a conductive dopant such as n-type or p-type dopant. Instead of the semiconductor substrate 100, another conductive layer can be used as an initial layer. The following steps may proceed. An etching stop layer 140, which is a material such as Si3N4, is formed on the semiconductor substrate 100 to serve as a stop layer of chemical mechanical polishing or etching in the sequential steps. Thereafter, the semiconductor substrate 100 is selectively etched to form a cylindrical trench 120 by photolithography and etching.

Referring to FIG. 2, a SiO₂ layer 160 is deposited on the area, i.e., the sidewall and the bottom, except the center of the trench 120 using low pressure chemical vapor deposition (LPCVD) in the presence of tetra-ethyl-ortho-silicate (TEOS). The SiO₂ layer 160 is extended to the upper surface of the semiconductor substrate 100.

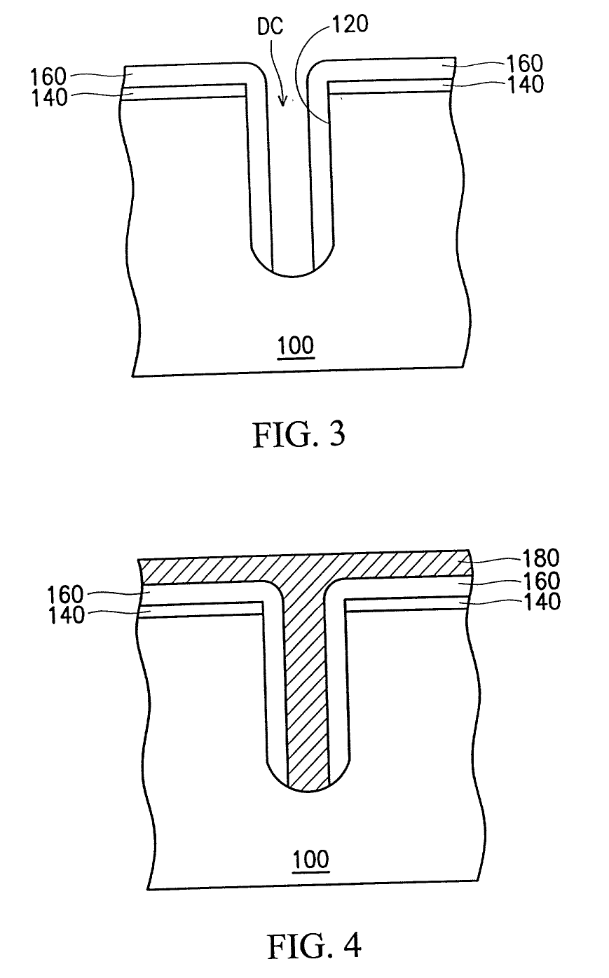

Referring to FIG. 3, the SiO₂ layer located on the bottom of the trench 120 is removed by anisotropic etching to expose the semiconductor substrate 100 at the center DC of the trench 120.

Referring to FIG. 4, a conductive layer 180, poly-silicon, is formed using in-situ doping LPCVD in the presence of SiH₄. The dopant used here has the same conductivity as that of the semiconductor substrate 100.

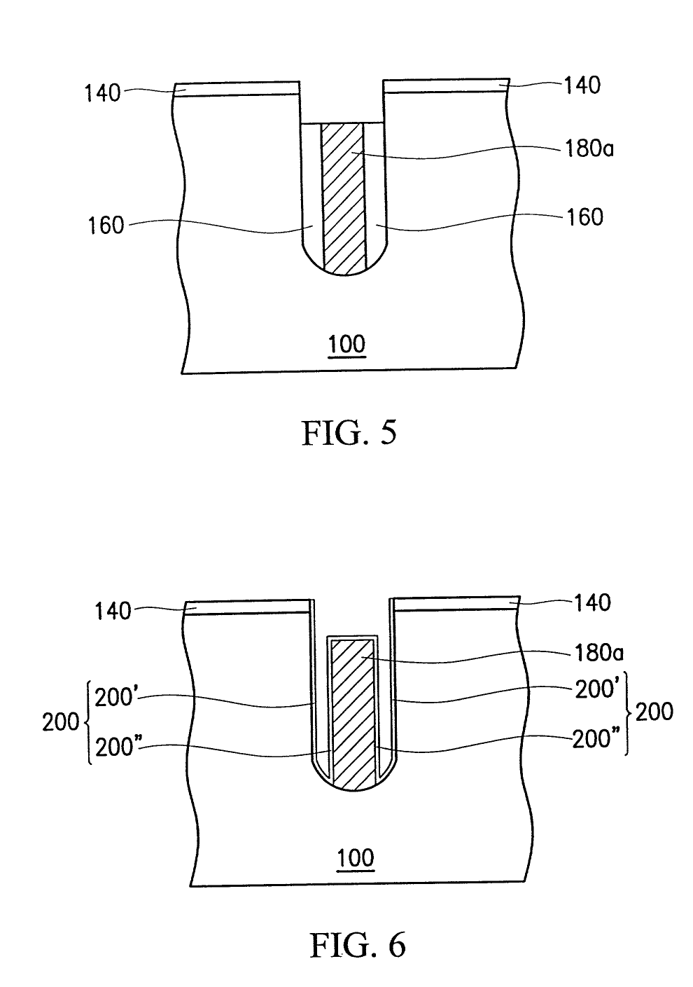

Referring to FIG. 5, the conductive layer 180 outside of the trench 120 is removed by CMP and etching back to form a conductive structure 180a whose height is less than that of the trench 120. At the same time, the SiO₂ layer 160 on the semiconductor substrate 100 is also removed. The conductive structure is used as a bottom plate of the trench capacitor. It should be noted that the bottom plate is constituted by the semiconductor substrate 100 and the conductive structure 180a in this embodiment.

Next, referring to FIG. 5 and FIG. 6, the SiO₂ 160 left on the sidewall of the trench 120 is removed using buffered oxide etchant (BOE) such as that including HF. A substantially conformal dielectric layer 200 is formed on the sidewall of the trench 120 and the conductive structure 180a by chemical vapor deposition. The dielectric layer 200 includes the dielectric layer 200′ formed on the sidewall of the trench and the dielectric layer 200″ formed on the conductive structure 180a. The dielectric layer 200 can be SiO₂/Si₃N₄/SiO₂ or Si₃N₄/SiO₂ and has a thickness of about 45˜50 Å. Instead of the above-described material, the dielectric layer 200 can be additional materials such as Ta₂O₅ and others.

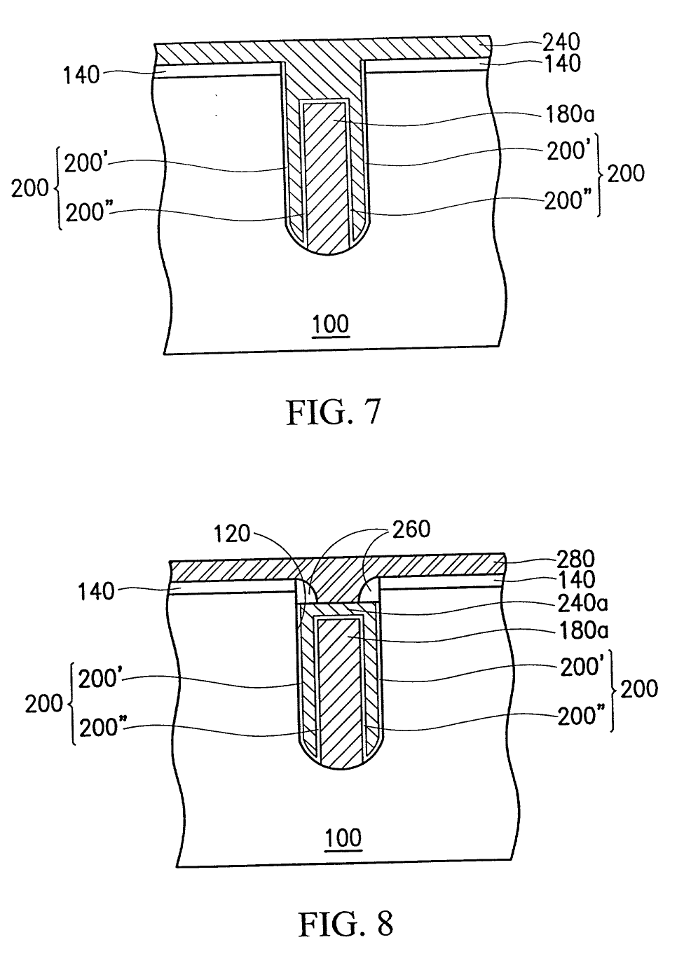

Referring to FIG. 7, a conductive layer 240, which is a material such as poly-silicon, is formed using in-situ doping LPCVD in the presence of SiH₄. The conductive layer 240 is filled between the dielectric layer 200′ and the dielectric layer 200″ to serve as the top plate.

Referring to FIG. 8, a part of the conductive layer 240 is removed by CMP to remain a conductive structure 240a, which is formed around the conductive structure 180a and between the dielectric layer 200′ and the dielectric layer 200″. Then, a sidewall isolator 260 is formed on the top of the trench 120 by depositing and etching back a layer of SiO₂. A conductive structure 280, which is a material such as poly-silicon, is formed on the semiconductor substrate 100 by using CVD. The purpose of forming the sidewall isolator 260 is to prevent the conductive structure 180 and the semiconductor substrate 100 from short-circuiting.

Accordingly, a semiconductor device having a trench capacitor fabricated by the above process includes a semiconductor substrate 100, which serves as a part of the bottom plate of the capacitor, having a cylindrical trench 120; a cylindrical conductive structure 180a formed in the trench 120, in which the bottom of the cylindrical conductive structure 180a is electrically connected to the semiconductor substrate 100 to serve as another part of the bottom plate; a dielectric layer 200′ formed on the sidewall of the trench 120; a ring-shaped conductive structure 240a, isolatedly formed around the conductive structure 180a, for serving as the top plate; a dielectric layer 200″, formed between the conductive structure 180a and the conductive structure 240a, for isolating the two conductive structures 180a and 240a; and a third conductive structure 280 formed on the semiconductor substrate 100 and electrically connected to the conductive structure 240a.

Referring to FIG. 9, the symbol C1 indicates the first capacitor which is constituted by the semiconductor substrate 100, the dielectric layer 200′ and the conductive structure 240a, and the symbol C2 indicates the second capacitor which is constituted by the conductive structure 180a, the dielectric layer 200″ and the conductive structure 240a. The capacitance is increased since the first capacitor C1 and the second capacitor C2 are connected in parallel. The symbol T in FIG. 9 indicates a MOS transistor. The drain of the transistor T is connected to the conductive structure 240a through the third conductive structure 280. The source of the transistor T is connected to the bit line BL, and the gate of the transistor T is connected to the word line WL.

According to the present invention, the semiconductor device having a trench capacitor can be provided with an improved storage capacitance when the trench has a predetermined depth.

Finally, while the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A semiconductor device having a trench capacitor including:
a semiconductor substrate having a trench formed thereon serving as a first bottom plate;
a first conductive structure formed in the trench, in which the bottom of the first conductive structure is electrically connected to the semiconductor substrate to serve as a second bottom plate;
a first dielectric layer formed on the sidewall of the trench;
a second conductive structure isolatedly formed around the first conductive structure to serve as a top plate;
a second dielectric layer formed between the first conductive structure and the second conductive structure to isolate the first conductive structure and the second conductive structure; and
a third conductive structure formed on the semiconductor substrate and electrically connected to the second conductive structure.

2. The semiconductor device as claimed in claim 1 wherein the trench is cylindrical.

3. The semiconductor device as claimed in claim 2 wherein the first conductive structure is cylindrical.

4. The semiconductor device as claimed in claim 3 wherein the second conductive structure is ring-shaped.

5. The semiconductor device as claimed in claim 1 wherein the height of the first conductive structure is less than that of the trench.

6. The semiconductor device as claimed in claim 5 further comprising a sidewall isolator, formed on the top of the trench, for isolating the third conductive structure and the semiconductor substrate.

7. The semiconductor device as claimed in claim 1 wherein the semiconductor substrate is monocrystalline silicon having a first conductivity type of dopant.

8. The semiconductor device as claimed in claim 7 wherein the first conductive structure, the second conductive structure and the third conductive structure are poly-silicon having a first conductivity type of dopant.

9. The semiconductor device as claimed in claim 1 wherein the first dielectric layer and the second dielectric layer are SiO₂/Si₃N₄/SiO₂.

10. The semiconductor device as claimed in claim 1 wherein the first dielectric layer and the second dielectric layer are Si₃N₄/SiO₂.

11. The semiconductor device as claimed in claim 1 wherein the semiconductor substrate, the first dielectric layer and the second conductive structure constitute a first capacitor, and the first conductive structure, the second dielectric layer and the second conductive structure constitute a second capacitor, in which the first capacitor and the second capacitor are connected in parallel.

12. A method for manufacturing a semiconductor device having a trench capacitor comprising the steps of:
providing a semiconductor substrate having a trench formed thereon, in which the semiconductor substrate serves as a first bottom plate;
forming a first conductive structure in the trench to serve as a second bottom plate;
forming a first dielectric layer and a second dielectric layer on the sidewall of the trench and on the first conductive structure, respectively;
filling a second conductive structure between the first dielectric layer and the second dielectric layer to serve as a top plate; and
forming a third conductive structure which is electrically connected to the second conductive structure.

13. The method as claimed in claim 12 wherein the process of forming the first conductive structure further comprises the steps of:
depositing an oxide layer on the sidewall of the trench;
anisotropically etching the oxide layer to expose the semiconductor substrate;
filling the trench with a first conductive layer; and
removing the first conductive layer outside of the trench to form a first structure having a height less than that of the trench.

14. The method as claimed in claim 13 further comprising a step of removing the oxide layer before the step of forming the first dielectric layer and the second dielectric layer.

15. The method as claimed in claim 13 further comprising a step of forming a sidewall isolator on top of the trench to isolate the third conductive structure and the semiconductor substrate before the step of forming the third conductive structure.

16. A semiconductor device of a trench capacitor comprises:
a first bottom plate;
a trench formed in the first bottom plate;
a second bottom plate formed in the trench and electrically connected to the first bottom plate;
a first dielectric layer formed on the first bottom plate and the second bottom plate;
a top plate formed on the first dielectric layer, whereby the top plate is isolated with the first bottom plate and the second bottom plate; in which
the first bottom plate, the top plate and the first dielectric layer constitute a first capacitor, the second bottom plate, the top plate and the first dielectric layer constitute a second capacitor, and the first capacitor is connected to the second capacitor in parallel.
